(19) United States
(12) Patent Application Publication
(10) Pub. No.: US 2014/0166082 A1
(43) Pub. Date: Jun. 19, 2014

(54) PHOTOVOLTAIC DEVICES WITH AN IMPROVED POSITIONING AND LOCKING FEATURES AND METHOD OF ASSEMBLY

(71) Applicants: Joseph A. Langmaid, Caro, MI (US); James R. Kennihan, Midland, MI (US); Ryan Gaston, Midland, MI (US); Keith Kauffmann, Ypsilanti, MI (US); Jie Feng, Midland, MI (US)

(72) Inventors: Joseph A. Langmaid, Caro, MI (US); James R. Kennihan, Midland, MI (US); Ryan Gaston, Midland, MI (US); Keith Kauffmann, Ypsilanti, MI (US); Jie Feng, Midland, MI (US)

(73) Assignee: DOW GLOBAL TECHNOLOGIES LLC, Midland, MI (US)

(21) Appl. No.: 14/234,705

(22) PCT Filed: Jul. 27, 2012
(86) PCT No.: PCT/US2012/048593

§ 371 Date: Jan. 24, 2014

Related U.S. Application Data
(60) Provisional application No. 61/513,263, filed on Jul. 29, 2011.

(51) Int. Cl. H01L 31/042; H01L 31/18

(52) U.S. Cl. CPC H02S 20/00; H01L 31/18
USPC 136/251; 29/525.01; 29/825

(57) ABSTRACT

The present invention concerns photovoltaic devices for mounting on a structure, e.g. photovoltaic roof tiles. The photovoltaic devices (100) comprise improved positioning and locking features (252, 254) that prevent adjoining devices from nesting unless the locking feature is engaged.

### CLAIM OF PRIORITY

The present application claims the benefit of the filing date of U.S. Provisional Application No. 61/513,263 filed on Jul. 2, 2011 the contents of which are hereby incorporated by reference in their entirety.

### FIELD OF THE INVENTION

The present invention relates to photovoltaic devices that include an improved positioning and locking feature and method of assembly, more particularly to locking features that also help prevent adjoining devices from nesting unless the locking feature is engaged.

### BACKGROUND

Efforts to improve PV (photovoltaic) devices particularly those devices that are integrated into building structures (e.g. photovoltaic sheathing elements, spacer pieces, edge pieces), to be used successfully, should satisfy a number of criteria. The PV devices may be commonly known as Building-integrated photovoltaics (BIPV). These BIPVs are typically PV devices (and associated system components) that are used to replace conventional building materials in parts of the building envelope such as the roof, skylights, or facades. The PV device and the array as installed should be durable (e.g. long lasting, sealed against moisture and other environmental conditions) and protected from mechanical abuse over the desired lifetime of the product, preferably at least 15 years, more preferably at least 25 years. The device should be easily installed into the array of devices (e.g. installation similar to conventional roofing shingles or exterior wall coverings) or replaced (e.g. if damaged).

In one exemplary configuration, BIPVs can be configured and installed in a similar fashion to that of traditional building cladding materials (e.g. roofing shingles/tiles or vinyl siding), in rows and columns, and particularly in partially overlapping rows.

It is not surprising that correct installation of each device is important, to ensure the functionality and durability of the system. Each device in a row may be electrically connected to one another during the installation and ensuring a good connection at the time of installation and during its functional lifetime) can be critical. Making it easy for the installer to visually check that there has been a proper installation can make the installation more robust and reliable.

Among the literature that can pertain to this technology include the following patent documents: WO/2009/137353A3; WO/2009/137352A3; WO/2009/137348A3; and WO/2009/137347A3; all incorporated herein by reference for all purposes and particularly for teachings on photovoltaic roofing or building sheathing element, arrays, and connectors.

### SUMMARY OF THE INVENTION

The present invention seeks to help solve one or more of the problems/issues disclosed above. The present invention is particularly directed to photovoltaic devices that include an improved positioning and locking feature and method of assembly, more particularly to locking features that may also provide at least visual clues that the adjoining devices are installed correctly.

Accordingly, pursuant to one aspect of the present invention, there is contemplated a photovoltaic device kit as mounted on a structure, the device kit comprising: one or more photovoltaic devices, each device including: an active portion that is framed on at least one side by an inactive portion, the inactive portion including lower surface portion that directly or indirectly contacts the structure and an upper surface portion that receives one or more fasteners that attaches the photovoltaic device to the structure, the inactive portion further including two or more positioning features adapted to regulate the relative position of and lock the relative position of at least a first and a second photovoltaic device as installed on the structure, wherein at least one locking feature from the first photovoltaic device mates to at least one locking feature from the second device.

Accordingly, pursuant to another aspect of the present invention, there is contemplated a method of assembling a photovoltaic device kit onto a building structure, comprising the steps of: A: providing a first photovoltaic device; B: providing a second photovoltaic device, each photovoltaic device including: an active portion that is framed on at least one side by an inactive portion, the inactive portion including lower surface portion that contacts the structure and an upper surface portion that receives one or more fasteners that attaches the photovoltaic device to the structure, the inactive portion further including one or more positioning features adapted to regulate the relative position of and lock the relative position of at least a first and a second photovoltaic device as installed on the structure, wherein the one or more one locking feature from the first photovoltaic device mates to the one or more one locking feature from the second device; C: placing the first photovoltaic device on the building structure; D: placing the second photovoltaic device on the building structure; E: sliding the first and second devices together to make en electrical connection between them; F: locking the one or more positioning features of the first and second devices together; G: providing at least two or inure fasteners; and H: fastening the first and the second photovoltaic devices to the building structure with the two or more fasteners.

The invention may be further characterized by one or any combination of the features described herein, such as the two or more positioning features comprise a projecting armature, a channel, or both; at least one of the two or more positioning features o the first photovoltaic device are adapted to prevent nesting of an adjacent structure to the kit unless it is mated to one or more positioning features of the second photovoltaic device; the one or more positioning features of the first photovoltaic device are adapted to prevent the use of one of the one or more fasteners unless it is mated to one or more positioning features of the second photovoltaic device; the projecting armature includes a hinge portion; the projecting armature includes a projecting button portion; the armature includes a fastener receiving feature that is adapted to receive one of the one or more fasteners that attaches the photovoltaic device to the structure; at least one of the two or more positioning features is integral to the body portion; at least one of the two or more positioning features is removable.

### DESCRIPTION OF THE DRAWINGS

FIGS. 1-15c relate to the present disclosure.

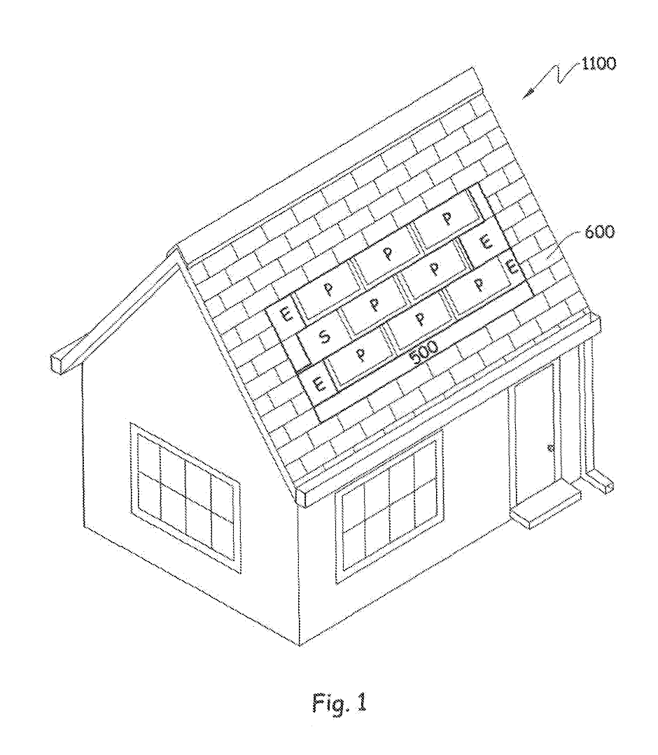

### DETAILED DESCRIPTION OF THE PREFERRED EMBODIMENT

Simply stated, the present invention is an improved positioning and locking feature and method of assembly for photovoltaic devices. Each component of the system may he described in further detail in the following paragraphs, in the drawings, or in the other patent applications that are incorporated by reference herein for the purposes stated.

It should be appreciated that the above and below referenced aspects, embodiments, and examples are non-limiting, as others, exist within the present invention, as shown and described herein.

Photovoltaic Rooting or Building Sheathing element/Device 100

It is contemplated that the PV sheathing device 100 may be a PV device “P”, or spacer device “S”, or edge pieces “E”, for example as described and disclosed in PCT publication 2009/137353 and corresponding U.S. patent application Ser. No. 12/989,743, incorporated herein by reference for the teachings of the structure of the photovoltaic device and the filler piece (AKA spacer devices “S”).

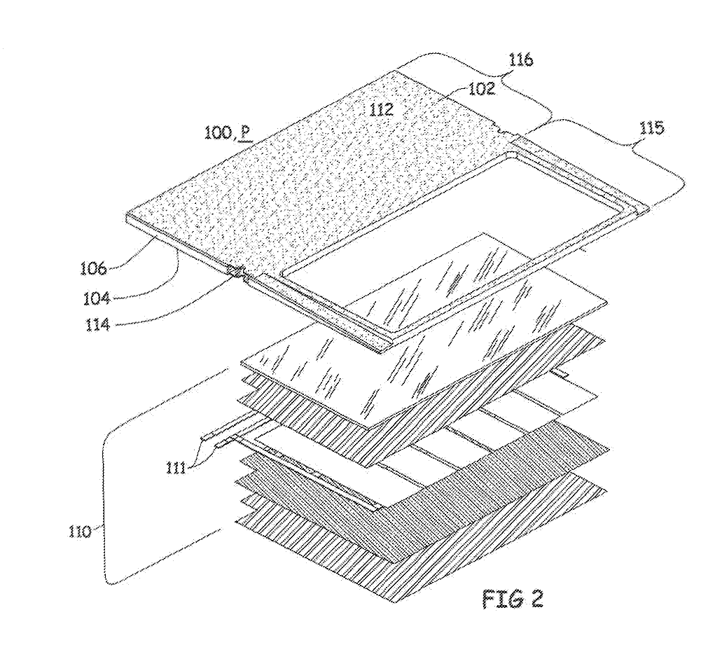

A PV device “P” functions as an electrical generating device that includes a functional element such as a photovoltaic cell assembly 111 within its structure. One illustrative example of a PV device “P” may be seen in FIG. 2, where an exploded view of a device “P” is shown. This illustrative example, shows a device “P” that is constructed of a multilayered laminate 110 that is surrounded (e.g. via over-molding) by a body portion 112. It may also be described as a device “P” that includes an active portion 115 and an inactive portion 116 wherein the inactive 116 portion encapsulates at least a portion of the peripheral edge of the active portion 115. Another possible stay to describe the active and inactive portions 115, 116 is that generally, the active portion 115 is visible and exposed when installed on a building and the inactive portion 116 generally is not visible or exposed. The device may also be described as having one or more fastening locations 118, which generally are disposed in the inactive portion 116, and may be marked graphically or textually.

An edge piece “E” generally functions to connect multiple rows of devices together, and may or may not include other functional elements. The edge piece also may serve as an interface between the side of the array 1000 and any adjoining materials (e.g. standard roofing/sheathing materials). A spacer device “S” generally may function to connect devices within a row, and may or may not include other functional elements.

The device 100, whether in the form of a PV device “P”, a spacer device “S”, or edge pieces “E”, can be further defined as having a top surface 102, a bottom surface 104 and a peripheral edge 106 spanning therebetween. It is also contemplated that the device 100 has an electrical connector (e.g. sheathing device electrical connector 114) disposed on or about the peripheral edge 106 that provides, the junction for electrical energy produced by the device (or the array). In a preferred embodiment, the peripheral edge 106 is about 35 mm or less in thickness, more preferably about 25 mm or less, most preferably about 20 mm or less, and about 5 mm or greater, more preferably about 10 mm or greater, and most preferably about 15 mm or greater, it is contemplated that in certain areas, for example on an edge piece “E”, where standard roofing/sheathing materials may be overlaid, the peripheral edge 106 may be as thin as 0.5 mm. Additionally, in the case of a spacer device “S” or edge piece “E” and for the purposes of this invention, the inactive portion 116 is generally considered that part of the device that is co-extensive with and/or above the sheathing device electrical connector 114.

The device 100 may also include one or more (preferably two or more) positioning features 150 adapted to regulate the relative position of and lock the relative position of at least e first and a second photovoltaic device 100 as installed on the structure, wherein at least one locking feature 150 from the first photovoltaic device 100 mates to at least one locking feature 150 from the second device 100. A more detailed explanation and illustrative examples of the locking feature 150 are provided in a separate section below.

It is preferred that the devices 100 are constructed primarily of a polymer (not including any functional elements such as the photovoltaic cells), although metallic materials are possible. Preferred materials or combinations of materials include a filled or unfilled moldable plastic (e.g. polyolefins, acrylonitrile butadiene styrene, hydrogenated styrene butadiene rubbers, polyester amides, polysulfone, acetel, acrylic, polyvinyl chloride, nylon, polyethylene terephthalate, polycarbonate, thermoplastic and thermoset polyurethanes, synthetic and natural rubbers, epoxies, styrene-acrylonitrile (“SAN”), polymethyl methacrylate, polystyrene, or any combination thereof). Fillers can include one or more of the following: colorants, fire retardant (“FR”) or ignition resistant (“IR”) materials, reinforcing materials, such as glass or mineral fibers, mineral filters, such as talc, calcium carbonate or mica, or surface modifiers. Materials may also include anti-oxidants, release agents, blowing agents, and other common additives plastic compositions.

The photovoltaic cell assembly 111 may comprise photovoltaic cells that are constructed of any material known to provide that function may be used including crystalline silicon, amorphous silicon, CdTe, GaAs, dye-sensitized solar cells (so-called Gratezel cells), organic/polymer solar cells, or any other material that converts sunlight, into electricity via the photoelectric effect. However, the photoactive layer is preferably a layer of IB-IIIA-chalcogenide, such as IB-IIIA-selenides, IB-III or IB-IIIA-selenide sulfides. More specific examples include copper indium selenides, copper indium gallium selenides, copper gallium selenides, copper indium sulfides, copper indium gallium sulfides, copper gallium selenides, copper indium sulfide selenides, copper gallium sulfide selenides, and copper indium gallium sulfide selenides (all of which are referred to herein as CIGSS).These can also be represented by he formula CuIn(1-x)GaxSe(2-y)Sy where x is 0 to 1 and y is 0 to 2. The copper indium selenides and copper indium gallium selenides are preferred. Additional electroactive layers such as one or more of emitter (buffer) layers, conductive layers (e.g. transparent conductive layers) and the like as is known in the art to be useful in CIGSS based cells are also contemplated herein. These cells may be flexible or rigid and come in a variety of shapes and sizes, but generally are fragile and subject to environmental degradation, in a preferred embodiment, the photovoltaic cell assembly 111 is a cell that can bend without substantial cracking and/or without significant loss of functionality. Exemplary photovoltaic cells are taught and described in a number of US patents and publications, including U.S. Pat. No. 3,767,471, U.S. Pat. No. 4,465,575, US20050011550 A1, EP 1706 A2, US20070256734 a1, EP1082051A2, JP2216874, JP2143468, and JP10189924a, incorporated hereto by reference for all purposes.

### Array of Devices/Elements 1000

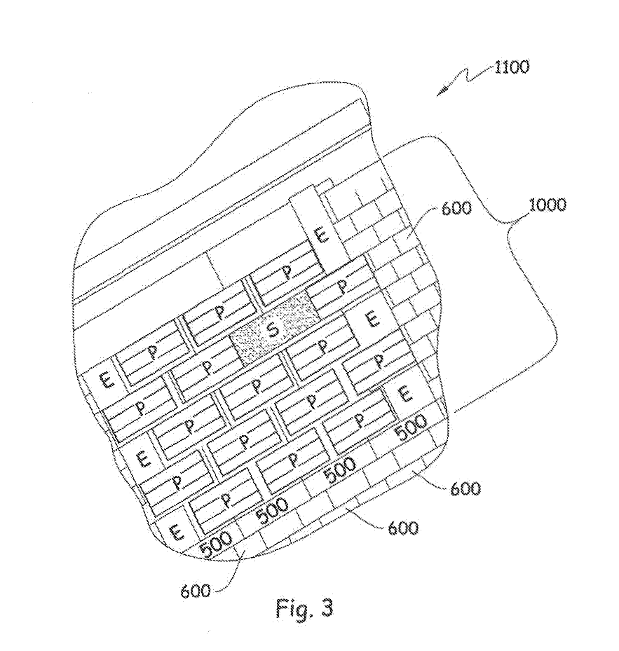

An array of devices (e.g. PV device “P”, spacer devices “S”, edge pieces “E”, etc.) function to provide electrical energy when subjected to solar radiation (e.g. sunlight). An array is a collection of interconnected devices as installed on a budding structure 1100. For the purposes of this invention, it is contemplated that the array 1000 is installed directly on an existing roof structure (or exterior surface) of a building structure 1100, over a roofing underlayment material (felt, self-adhered water barrier, fire-retardant layer, or moisture barrier sheet), or over a previously installed roofing material (e.g. asphalt shingles), in the same way traditional roofing elements are applied (unless otherwise noted herein). In a preferred embodiment, these arrays 1000 may be made up of two or more rows of adjoining devices, the rows containing at least two or more devices themselves. One or more interface members 500 described in more detail below, may be disposed on the bottom of the array 1000. As an illustrative example, at least partially shown in FIG. 3, the array 1000 presented has 6 rows, multiple devices per row including an edge piece on each end and one exemplary illustration of interface members 500 making up the bottom row of the array (row 6). The focus of this invention is how locking features 150 may resolve one or more of the problems/issues previously discussed, as well as potentially providing additional features that make installation more robust.

### Interface Members 500

An interlace member 500 function to provide an interface row between the PV sheathing devices 100 and any non-PV sheathing device cladding materials (e.g. traditional asphalt shingles, premium roofing material such as concrete tile or natural slate, or similar components, herein referred to as a “sheathing member” 600). The member or members 500 may provide a nesting portion for both the PV sheathing devices 100 and for the sheathing member 600. It is contemplated that the member may allow for the installation/removal of devices 100 and/or members 600 independently of each other arid in any order.

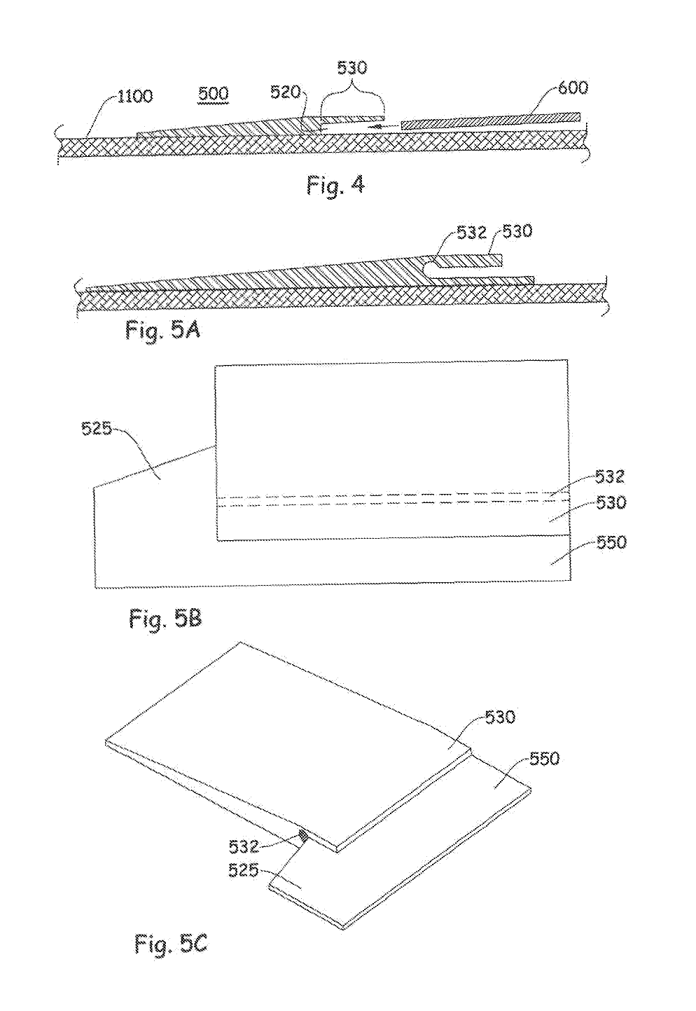

It is contemplated that the interface member 500 may at least be a three dimensional component that includes a PV sheathing element resting portion 510 and a building sheathing nesting portion 520. Exemplary embodiments and variations are discussed in detail below. The PV sheathing element nesting portion 510 functions as receiving area for the devices 100, wherein typically the device sits on top of the nesting portion in the installed position. It is contemplated that the nesting portion may include positioning features that aid in locating the devices. The building sheathing nesting portion 520 functions as at least receiving area for the sheathing members 600, wherein the member 600 at least abuts the nesting portion, for example as shown in FIG. 4. It is also contemplated that the member 500 may include horizontal overlap portions 525, for example as shown in FIGS. 5A, B and C, which function to provide an interface/overlap area between the side of the member and horizontally adjoining sheathing members 600. FIGS. 5A, B and C also thaw a living hinge 532 for the member 500, a nesting portion 520, an integral upper flashing portion 530, a lower flashing portion 550 and a horizontal overlap portion 525. FIG. 5A is a side view. 5B is a view with dotted lines showing the location of the living hinge 532 not visible from this perspective. 5C is a perspective view where the side of the living hinge 532 is shown and the unseen path of the living hinge is shown by dotted lines.

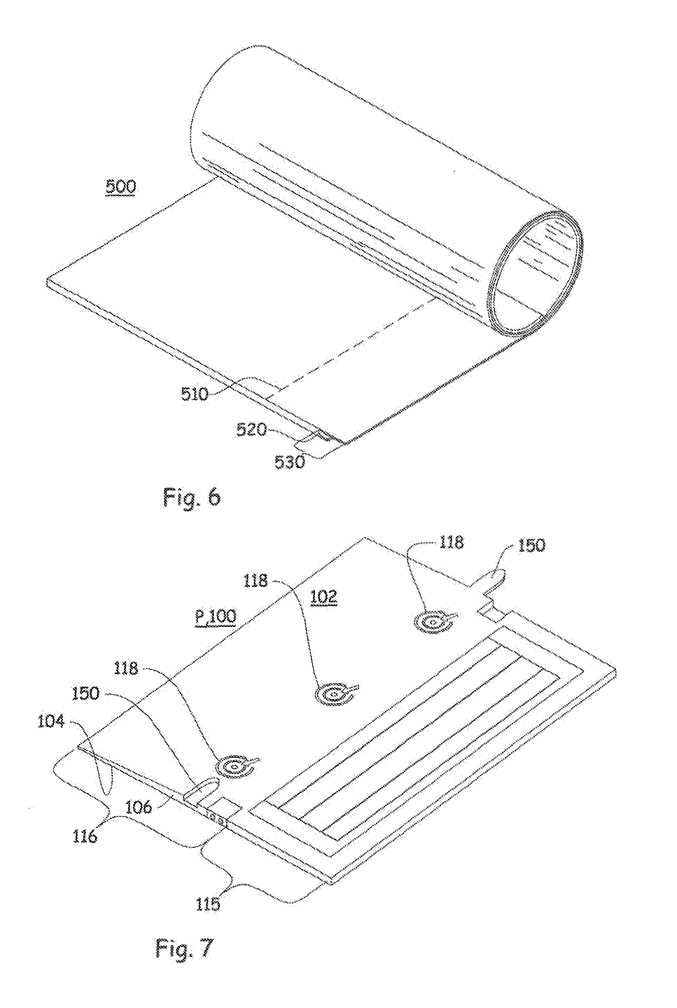

It is contemplated that the interface member 500 may be in the form of a discrete component (e.g. a panel-like member akin to devices 100) or may be in a continuous roll form, for example as shown in FIGS. 4 and 6 respectively.

In a preferred embodiment, the member 500 is constructed essentially of a polymeric material. Preferred materials or combinations of materials include a filled or unfilled moldable plastic (e.g. polyolefins, acrylonitrile butadiene styrene, hydrogenated styrene butadiene rubbers, polyester amides, polysulfone, acetel, acrylic, polyvinyl chloride, nylon, polyethylene terephthalate, polycarbonate, thermoplastic and thermoset polyurethanes, synthetic and natural rubbers, epoxies, styrene-acrylonitrile (“SAN”), polymethyl methacrylate, polystyrene, or any combination thereof). Fillers can include one or more of the following; colorants, fire retardant (“FR”) or ignition resistant (“IR”) materials, reinforcing materials, such as glass or mineral fibers, mineral fillers, such as talc, calcium carbonate or mica, or surface modifiers. Plastic can also include anti oxidants, release agents, blowing agents, and other common plastic additives.

In the case where the member 500 is in a continuous roll form, the preferred materials include: Polyolefins; hydrogenated styrene butadiene rubber; polyesters; polyamides; polyesteramides; poly (vinyl chloride); synthetic and natural rubbers; EPDM; asphalt type compounds (i.e., shingle like material). Plastic can also include anti-oxidants, release agents, blowing agents, and other common plastic additives

### Locking Feature 150

It is contemplated that the device 100 may include one or more locking features 150, and preferably two or more per device (e.g. one on opposing edge, for example as shown in FIG. 7). The locking device functions as a mechanism for locating or positioning and locking one device to another adjoining device. Preferably it functions to assure that the electrical connection between the devices is properly made during assembly and possibly aids in maintaining it during the product life cycle (although the fasteners 260 hold the device 100 to the structure). It also may function as a visual assembly aid, wherein an adjoining device 100 has a gap “G” when the locking feature 150 is not properly nested, for example as shown in FIGS. 13A and 13B. Furthermore, it may function to prevent the installation of one or more fasteners (e.g. nails, screws, or the like) when the locking feature 150 is not properly nested.

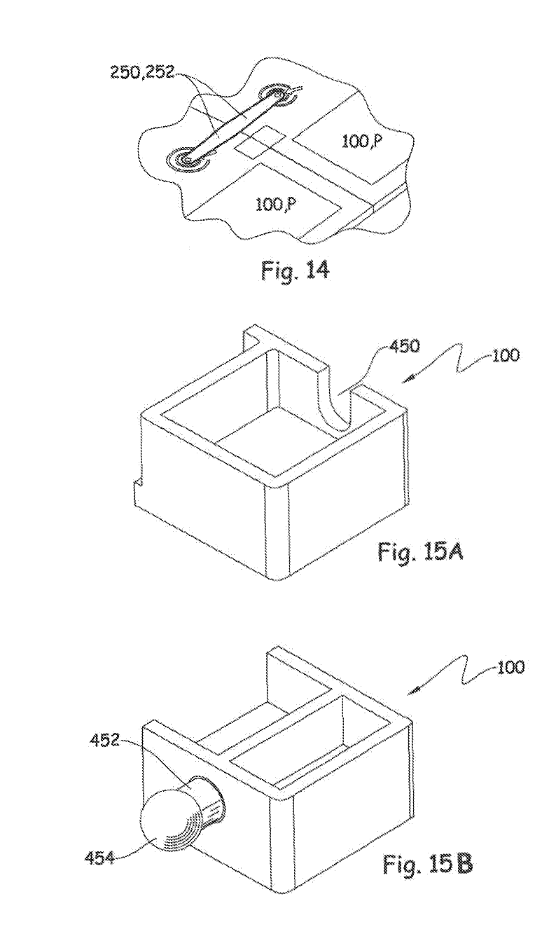

It is contemplated that the locking feature may be an integral part of the device 100, or may be a combination of integral and separate pieces, for example as shown in FIG. 14. It is possible that the locking feature 150 may be disposed on the to surface 102, the bottom surface 104, or the peripheral edge 106 of the device, but in a preferred embodiment, is disposed on the top surface 102, more preferably in proximity (spanning across or within about 15.0 mm) to the sheathing device electrical connector 114, for example as shown in FIG. 7.

As stated above, the locking device functions as a mechanism for locating or positioning and locking one device to another adjoining device. It is contemplated that the locking device may provide for positioning with a positional tolerance. In a preferred embodiment, the total positional tolerance provided by the locking device is about 1.0 mm or less and about +/−0.1 mm or more.

Several examples are provided below. The examples should not be considered limiting and are for illustrative purposes.

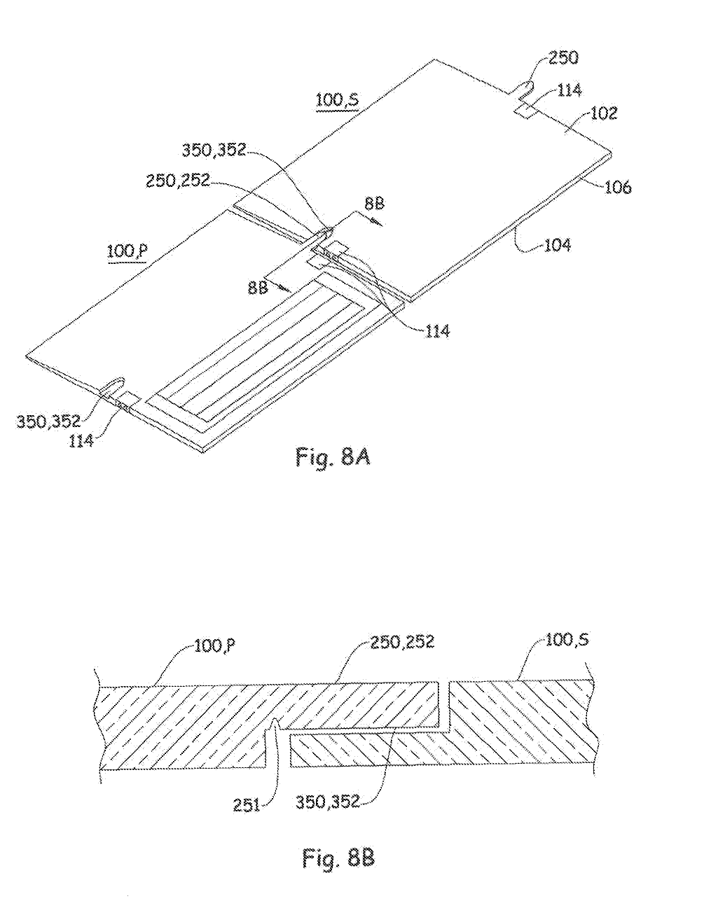

In a first illustrative example, as shown in FIGS. 8A and 8B, a first and second device 100 are shown. Each device 100 has a first locking feature 250 on one side of the top surface 102 and a second locking feature 350 on the opposing side. The features 250, 350 are configured to mate when brought together (e.g. feature 250 on the first device 100 to feature 350 on the second device). In this example, the feature 250 includes a projecting armature 252. The feature 350 includes a channel 352 that is adapted to receive the projecting armature 252. Additionally, in this example, an optional hinge portion 251 is disposed on the armature, generally near the edge of the device. The hinge portion 251 functioning to allow the movement of the armature 252 with less force than if the hinge portion was not included. As shown, the hinge portion 251 may be a locally thinned out area of the projecting armature, although other designs are contemplated.

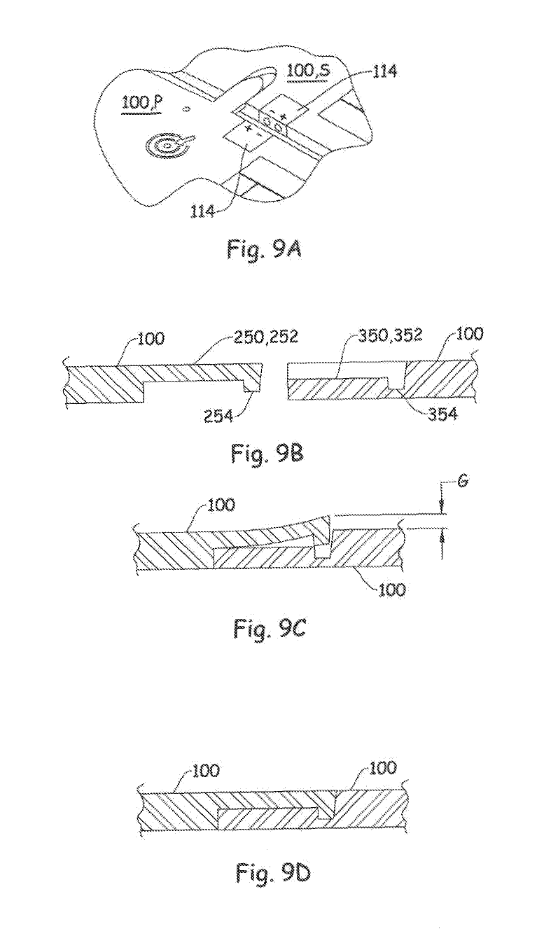

In a second illustrative example, as shown in FIGS. 9A through 9D, the locking features are similar to that of the first example, including a projecting armature 252 and a channel 352. In this example, there is an addition of a downwardly projecting button portion 254 and corresponding receiving channel portion 354 for button 254.

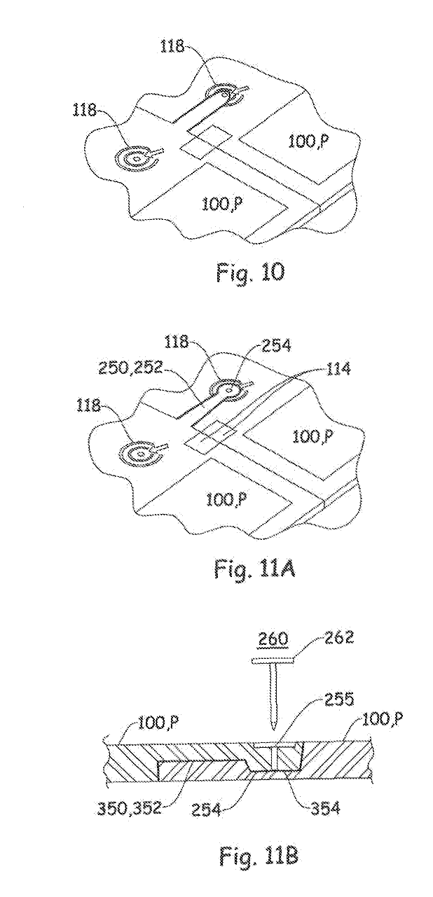

In a third illustrative example, as shown in FIGS. 9 and 10, the locking features are similar to that of the second example, with the addition of a preferred configuration for the projecting armature 252, the channel 352 the downwardly projecting button portion 254 and corresponding receiving channel portion 354. In this example, the configuration/dimensions are such that the projecting armature 252 and channel 352 are sufficiently long enough and positioned such that the downwardly projecting button portion 254 and corresponding receiving channel portion 354 would prevent the use of one of the one or more fasteners unless they are mated to one another. Preferably, the location of the downwardly projecting button portion 254 and corresponding receiving channel portion 354 are in-line with at least one the fastening locations 118 as shown in the figures.

In a fourth illustrative example, as shown in FIGS. 11A and 11B, the locking features are similar to that of the third example, with the addition of a preferred configuration for the downwardly projecting button portion 254 and corresponding receiving channel portion 354. In this example, the button portion 254 and the receiving channel portion 354 are configured to be larger than a head portion 262 of a fastener 260 that is intended to be used at that fastening location 118. Functionally, this would not allow the fastener head portion 262 to be seated on the device properly and would signal to an installer that something was not correct. Additionally, the button portion 254 may optionally include a fastener guide 255, which is adapted to either hold a fastener in-place (e.g. before nailing) or may be slightly larger than the shaft of the fastener (e.g. about 5 to about 20 percent).

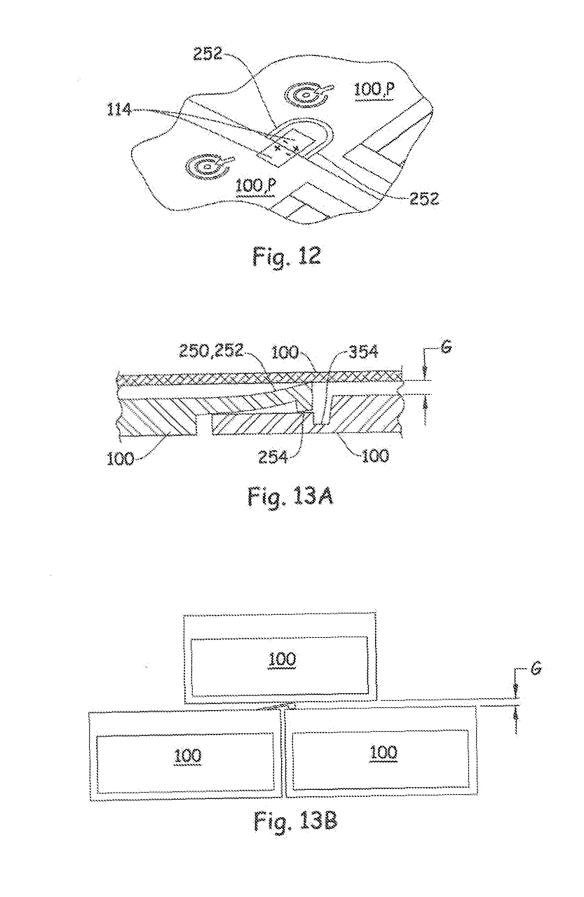

In a fifth illustrative example, as shown in FIG. 12, the projecting armature 252 and channels 352 are in two sections that straddle the sheathing device electrical connector 114. It is contemplated that this may be preferably if, for example, the rotational adjustment or movement of the connector 114 is desired.

It should be noted, that in any of the above examples when the locking feature 150 is not fully engaged, the projecting armature would project above the surface of the device 100, and prevent full nesting of an adjacent structure and create, for example, gap “G”, seen generally FIG. 9C and FIGS. 13A and B (FIG. 13B shows a locking feature disposed on the peripheral edge 106).

In a sixth illustrative example, as shown in FIG. 14, the projecting armature 252 is a separate piece and corresponding receiving channel portions 352 are disposed within the first and second devices 100. In the case where a separate piece may be used, the choice of materials can be expanded. It is contemplated that ideally the material has thermal expansion properties such that definition of installation tolerance can be met over all assembly temperatures, usually ranging from about 0° C. to about 50° C. and service temperatures up to, about 90° C. This allows the locking devices to be made of most any polymeric material with a CLTE of about 300×10-6 mm/mm° C. or less. More preferably about 120×10-6 mm/mm° C. or legs, most preferably about 30×10-6 mm/mm° C. or less, (Based on this, the same material list as used in the body material can be used, with and without fillers.)

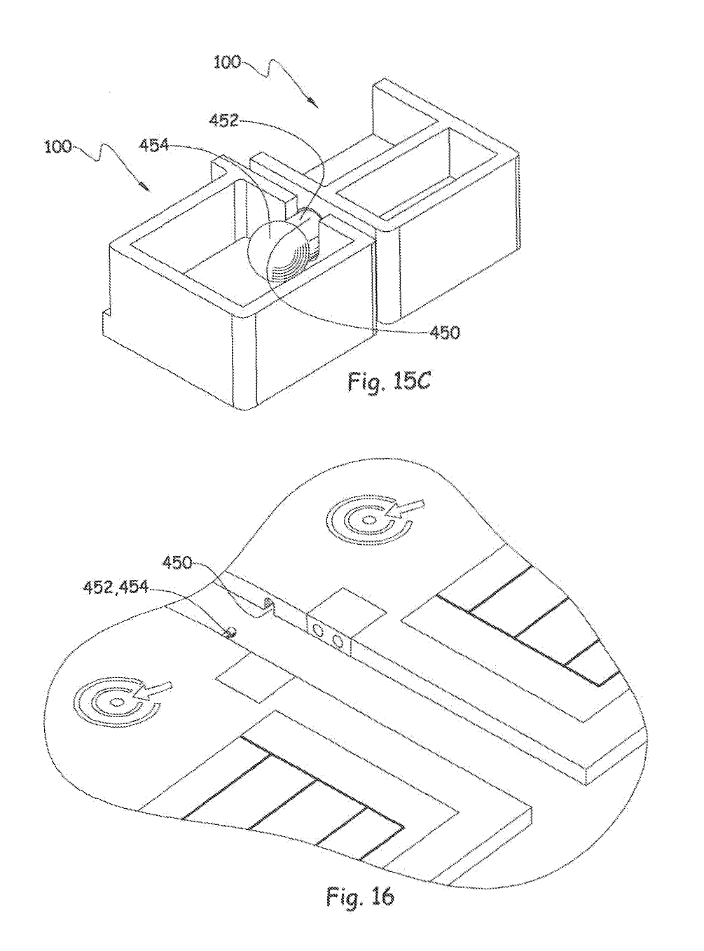

The locking feature can comprise an armature along one edge of a photovoltaic device and a channel, e.g. opening or slot, on a second photovoltaic device which creates an interference fit on the armature. An armature as used herein is an elongated projection along one edge of the body of a photovoltaic device adapted to fit and preferably interlock with a mating feature of an adjacent body portion of a photovoltaic device. In some embodiments the armature may include a button portion adapted to effectuate interlocking of the armature in a mating feature of an adjacent photovoltaic device. The button may be a projection from the armature in the horizontal and/or vertical planes or an enlarged portion of the armature. A mating feature is an opening, channel, indentation or a combination thereof adapted to receive the armature and optionally a button so as to interlock the armature and optional button with respect to an adjacent photovoltaic device. The armature on the first device may not contain a hinge portion, but be constructed in the axis of the installation motion to lock directly into the channel or slot on the second device. The armature can be slightly larger than the channel so that once it is inserted it is locked in place. Alternatively the armature may have a button end portion larger than the channel such that the larger button portion resists passing through the channel and holds the two adjacent photovoltaic devices together. The larger button portion is larger than the portion of the armature that is placed in the channel and is adapted to be placed on the inside of the channel of a second photovoltaic device so as to lock two adjacent photovoltaic devices together (locking feature). The armature and the channel preferably have corresponding shapes such that the adjacent photovoltaic devices can be rotated with respect to another, that is they are not fully in line with respect to each other, but generally in the same plane, so as to facilitate adjustment, removal of one or placement or replacement of one or more electrical connectors. In the embodiment wherein the button portion of the armature to be placed in the channel is larger than the channel, the size difference is selected such that the armature can be placed in the channel using reasonable force. Preferably the ratio of the size of the portion of the armature placed in the channel to the size of the channel that the armature is placed in is about 1.10:1.0 or less and preferably 1.07:1.0 or less. Preferably the force needed to place the armature in the channel is about 60 N or less and more preferably 45 N or less and about 10 N or greater and more preferably about 15 N or greater. FIGS. 15A to C illustrate one embodiment of this feature. 15A shows a cut out from a photovoltaic device showing a channel 450 adapted to receive an armature 452 (not shown). 15B shows a cut out from a second photovoltaic device 100 having an armature 452 wherein the armature has a button with a ball shaped tip 464 adapted to be placed in adjacent to and inside of channel 450 of an adjacent photovoltaic device. 15C illustrates the armature 452 placed in a channel 450 wherein the ball tip 454 is disposed inside of the channel 450 to lock the devices together. The connector parts can be integrated into the inactive portion of the photovoltaic device (integral to) or can be separate parts inserted into or attached to the photovoltaic devices. FIG. 15D illustrates an example of the general location of a horizontally interfaced armature 452 with a locking button portion 454 on a first device and a corresponding opening 450 on a second device.

For the integrated locking feature, preferably has an ultimate elongation of at least about 1% at greater, more preferably about 2.5% or greater, and most preferably about 5% or greater.

In the case of the independent componet, it becomes more preferable to have a lower CLTE (e.g. above ranges/2). In order for the more difficult tolerances to be met, it will preferably be made of a material with about 5% by weight or greater inorganic compound. For higher tolerance interfaces, the material can be made of a very rigid material, such as metal, ceramic, or more highly filled polymers. The elongation requirements may not apply.

These material properties may be most important during the assembly process. After assembly, positions may be determined by the attachment of the devices to the building. Alternately, the locking feature may be designed so as to limit relative motion between devices more rigidly during the service life of the product. For example, a material, that is extremely stable over the devices life may be chosen to prevent relative movements in the roofing materials from moving the devices with respect to each other. In this case, the locking feature may be of such items as stamped steel (usually galvanized, zinc plated, painted, or with other similar corrosion barriers), stainless steel, aluminum, ceramics, cement, or other materials with high resistance to stress related movements.

### Method

It is contemplated in the present invention that the installation method provide herein is unique and aids in resolving one or more of the issues identified earlier in the application. The method may include at least the steps of: A: providing a first photovoltaic device; B: providing a second photovoltaic device, each photovoltaic device including: an active portion that is framed on at least one side by an inactive portion, the inactive portion including lower surface portion that contacts the structure and an upper surface portion that receives one or more fasteners that attaches the photovoltaic device to the structure, the inactive portion further including one or more positioning features adapted to regulate the relative position of and lock the relative position of at least a first and a second photovoltaic device as installed on the structure, wherein the one or more one locking feature from the first photovoltaic device mates to the one or more one locking feature from the second device; C: placing the first photovoltaic device on the building structure; D: placing the second photovoltaic device on the building structure; E: sliding the first and second devices together to make an electrical connection between them; F: locking the one or more positioning features of the first and second devices together; G: providing at least two or more fasteners; and H: fastening the first and the second photovoltaic devices to the building structure with the two or more fasteners. It is contemplated that some or all of these steps may proceed in a different order, for example, the fastening of the first device to the building may happen before the sliding step E, so long as the step of locking the two devices together happens before both devices are secured to the building structure.

It is contemplated and expressly stated herein that the embodiments or examples described above may not be mutually exclusive and may be used in combination with each other.

Unless stated otherwise, dimensions and geometries of the various structures depicted herein are not intended to be restrictive of the invention, and other dimensions or geometries are possible. Plural structural components can be provided by a single integrated structure. Alternatively, a single integrated structure might be divided into separate plural components. In addition, while a feature of the present invention may have been described in the context of only one of the illustrated embodiments, such feature may be combined with one or more other features of other embodiments, for any given application. It will also be appreciated from the above that the fabrication of the unique structures herein and the operation thereof also constitute methods in accordance with the present invention.

The preferred embodiment of the present invention has been disclosed. A person of ordinary skill in the art would realize however, that certain modifications would come within the teachings of this invention. Therefore, the following claims should be studied to determine the true scope and content of the invention.

Any numerical values recited in the above application include all values from the lower value to the upper value in increments of one unit provided that there is a separation of at least 2 units between any lower value and any higher value. As an example, if it is stated that the amount of a component or a value of a process variable such as, for example, temperature, pressure, time and the like is, for example, from 1 to 90, preferably from 20 to 80, more preferably from 30 to 70, it is intended that values such as 15 to 85, 22 to 68, 43 to 51, 30 to 32 etc. are expressly enumerated in this specification. For values which are less than one, one unit is considered to be 0.0001, 0.001, 0.01 or 0.1 as appropriate. These are only examples of what is specifically intended and all possible combinations of numerical values between the lowest value and the highest value enumerated are to be considered to be expressly stated in this application in a similar manner.

Unless otherwise stated, all ranges include both endpoints and all numbers between the endpoints. The use of “about” or “approximately” in connection with a range applies to both ends of the range. Thus, “about 20 to 30” is intended to cover “about 20 to about 30”, inclusive of at least the specified endpoints.

The disclosures of all articles and references, including patent applications and publications, are incorporated by reference for all purposes.

The term “consisting essentially of” to describe a combination shall include the elements, ingredients, components or steps identified, and such other elements ingredients, components or steps that do not materially affect the basic and novel characteristics of the combination.

The use of the terms “comprising” or “including” describing combinations of elements, ingredients, components or steps herein also contemplates embodiments that consist essentially of the elements, ingredients, components or steps.

Plural elements, ingredients, components or steps can be provided by a single integrated element, ingredient, component or step. Alternatively, a single integrated element, ingredient, component or step might be divided into separate plural elements, ingredients, components or steps. The disclosure of “a” or “one” to describe an element, ingredient, component or step is not intended to foreclose additional elements, ingredients, components or steps. All references herein to elements or metals belonging to a certain Group refer to the Periodic Table of the Elements published and copyrighted by CRC Press, Inc., 1989. Any reference to the Group or Groups shell be to the Group or Groups as reflected in this Periodic Table of Elements using the IUPAC system for numbering groups.

1. A photovoltaic device kit as punted on a structure, the device kit comprising:
one or more photovoltaic devices, each device including:
an active portion that is framed on at least one side by an inactive portion, the inactive portion including lower surface portion that directly or indirectly contacts the structure and an upper surface portion that receives one or more fasteners that attaches the photovoltaic device to the structure, the inactive portion further including two or more positioning features adapted to regulate the relative position of and lock the relative position of at least a first and a second photovoltaic device as installed on the structure, wherein at least one locking feature from the first photovoltaic device mates to at least one locking feature from the second device wherein at least one of the two or more positioning features of the first photovoltaic device are adapted to prevent nesting of an adjacent structure to the kit unless it is mated to one or more positioning features of the second photovoltaic device.

2. The photovoltaic device kit according to claim 1, wherein the two or more positioning features comprise a projecting armature, a channel, or both.

3. (canceled)

4. The photovoltaic device kit according to claim 1, wherein the one or more positioning features of the first photovoltaic device are adapted to prevent the use of one of the one or more fasteners unless it is mated to one or more positioning features of the second photovoltaic device.

5. The photovoltaic device kit according to claim 2, wherein the positioning features comprise a projecting armature which includes a hinge portion.

6. The photovoltaic device kit according to claim 2, wherein the positioning features comprise a projecting armature which includes a projecting button portion.

7. The photovoltaic device kit according to claim 2, wherein the positioning features comprise a projecting armature which includes a fastener receiving feature that is adapted to receive one of the one or more fasteners that attaches the photovoltaic device to the structure.

8. The photovoltaic device kit according to claim 1, wherein at least one of the two or more positioning features is integral to the body portion.

9. The photovoltaic device kit according to claim 1, wherein at least one of the two or more positioning features is removable.

10. (canceled)

11. The photovoltaic device kit according to claim 1 wherein the positioning features comprise a projecting armature of one or more photovoltaic devices contains a button or locking feature comprising a portion of the armature that forms an interference fit in the channel of one or more adjacent photovoltaic devices and is adapted to be located inside of the channel in the one or more adjacent photovoltaic devices.

12. A method of assembling a photovoltaic assembly onto a building structure, comprising the steps of:
providing the kit of claim 1;
placing a first photovoltaic device from the kit on the building structure;
placing a second photovoltaic device from the kit on the building structure;
sliding the first and second devices together to make an electrical connection between them;
locking the one or more positioning features of the first and second devices together;
providing at least two or more fasteners; and
fastening the first and the second photovoltaic devices to the building structure with the two or more fasteners.

13. The method of claim 12 further comprising one or more additional photovoltaic devices from the kit, placing each of the one or more additional photovoltaic devices on the building structure adjacent to the first device, the second device or an earlier placed one of the one or more additional photovoltaic devices from the kit, and electrically connecting the adjacent devices, locking the one or more positioning features of adjacent devices together and fastening the additional photovoltaic devices to the building structure.

14. The method according to claim 13, wherein the two or more positioning features comprise a projecting armature, a channel, or both.

15. The method according to claim 13, wherein the one or more positioning features of the first photovoltaic device are adapted to prevent the use of one of the one or more fasteners unless it is mated to one or more positioning features of the second photovoltaic device.

16. The method according to claim 14, wherein the positioning features comprise a projecting armature which includes a hinge portion.

17. The method according to claim 14, wherein the positioning features comprise a projecting armature which includes a projecting button portion.

18. The method according to claim 14, wherein the positioning features comprise a projecting armature which includes a fastener receiving feature that is adapted to receive one of the one or more fasteners that attaches the photovoltaic device to the structure.

19. The method according to claim 13, wherein at least one of the two or more positioning features is integral to the body portion.

20. The method according to claim 14 wherein the positioning features comprise a projecting armature of one or more photovoltaic devices which contains a button or locking feature comprising a portion of the armature that forms an interference fit in the channel of one or more adjacent photovoltaic devices and is adapted to be located inside of the channel in the one or more adjacent photovoltaic devices.

21. The method according to claim 14 wherein the positioning features comprise a projecting armature which forms an interference fit in the channel.
